(19) United States
(12) Patent Application Publication
(10) Pub. No.: US 2015/0112623 A1
(43) Pub. Date: Apr. 23, 2015

(54) STRUCTURE FOR MEASURING DOPING REGION RESISTANCE AND METHOD OF MEASURING CRITICAL DIMENSION OF SPACER

(71) Applicant: UNITED MICROELECTRONICS CORP., Hsin-Chu City (TW)

(72) Inventors: Chien-Kuo Wang, Keelung City (TW); Chun-Liang Hou, Hsinchu County (TW); Wen-Jung Liao, Hsinchu City (TW)

(73) Assignee: UNITED MICROELECTRONICS CORP., Hsin-Chu City (TW)

(21) Appl. No.: 14/059,450

(22) Filed: Oct. 22, 2013

(51) Int. Cl. H01L 21/66

(52) U.S. Cl. CPC H01L 22/32
USPC 702/65; 257/48

(57) ABSTRACT

A method of the measuring a critical dimension of a spacer is provided. The measurement is performed by using several test structures of measuring doping region resistance. Each of the test structure has different space disposed between a first gate line and a second gate line. By measuring a doping region resistance of each test structure, a plot of reciprocal of resistance versus space can be accomplished. Then, making regression of the plot, a correlation can be formed. Finally, a critical dimension of a spacer can be get by extrapolating the correlation back to 0 unit of reciprocal of resistance.

### BACKGROUND OF THE INVENTION

1. Field of the Invention

This invention relates generally to a test structure for measuring doping region resistance and a method of measuring a critical dimension of a spacer.

2. Description of the Prior Art

Metal Oxide Semiconductor (MOS) technology has dominated the semiconductor process industry for a number of years. In its basic form, a MOS device includes a source, a drain, a gate between the source and the drain, and a spacer surrounding the gate. The performance of the MOS device may be influenced by a critical dimension of the spacer on the gate, a width of the gate or and other dimensions of structures of the MOS device.

Therefore, with the increasing integration density and operating frequencies of microelectronic devices, manufacturing processes for the MOS devices require the ability to measure dimensions of submicron structures. Conventionally, in-line measurements such as optical measurements are performed after the MOS devices created.

As MOS device dimensions become smaller than or comparable to the light wavelength, simple imaging such as microscopy is not possible, and the measurements require analysis of the intensity and/or the polarization state of the light scattered off the sample structure. Furthermore, the optical measurement is time-consuming.

### SUMMARY OF THE INVENTION

Therefore, one object of the present invention is to provide a novel method of measuring a critical dimension of a spacer, and a test structure for measuring doping region resistance is also provided in the present invention.

According to one preferred embodiment of the present invention, a structure for measuring doping region resistance, comprising: a substrate, a first gate line disposed on the substrate, a second gate line disposed parallel and adjacent to the first gate line, a first spacer disposed one a sidewall of the first gate line, a second spacer opposing to the first spacer disposed on a sidewall of the second gate line and a doping region disposed within the substrate between the first spacer and the second spacer, and the doping region extend continuously along the first gate line from a front end of the first gate line to a back end of the first gate line.

According to another preferred embodiment of the present invention, a method of measuring a critical dimension of a spacer, comprising the steps of: first, providing numerous test structures, each of the test structures comprising: a substrate, a first gate line disposed on the substrate, a second gate line disposed parallel and adjacent to the first gate line, a first spacer disposed on one a sidewall of the first gate line, a second spacer opposing to the first spacer disposed on a sidewall of the second gate line, wherein each of the test structures has a doping region different in size, the doping region is disposed in the substrate and between the first gate line and the second gate line, and each of the test structures has a space disposed between the first gate line and the second gate line, and the space of each of the test structures is different. Then, a voltage difference is applied to each of the doping regions, and a current flowing through each of the doping region is measured under the voltage difference to get several current values. Later, a reciprocal of resistance of each of the doping regions is calculated based on the current values and the voltage difference. Thereafter, a plot of reciprocal of resistance versus space is drawn based on the reciprocal of resistance of each test structure and the space of each test structure. Subsequently, a regression is made to the plot to form a correlation. Finally, the correlation is extrapolated back to 0 unit of reciprocal of resistance to determining two times of a critical dimension of the first spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 are schematically illustrate a method of measuring a critical dimension of a spacer according to a preferred embodiment of the present invention, wherein:

FIG. 1 shows schematically a top view of a test structure for measuring doping region resistance;

FIG. 2 shows schematically a cross-sectional view of the test structure in FIG. 1 along line A-A′;

FIG. 3 shows schematically a cross-sectional view of the test structure in FIG. 1 along line B-B′;

FIG. 4 shows schematically numerous test structures disposed on a wafer;

FIG. 5 illustrates cross-sectional views of another test structure;

FIG. 6 illustrates cross-sectional views of yet another test structure;

FIG. 7 shows a plot of reciprocal of resistance versus space of test structure; and

FIG. 8 illustrates a cross-sectional view of a test structure having smallest space.

### DETAILED DESCRIPTION

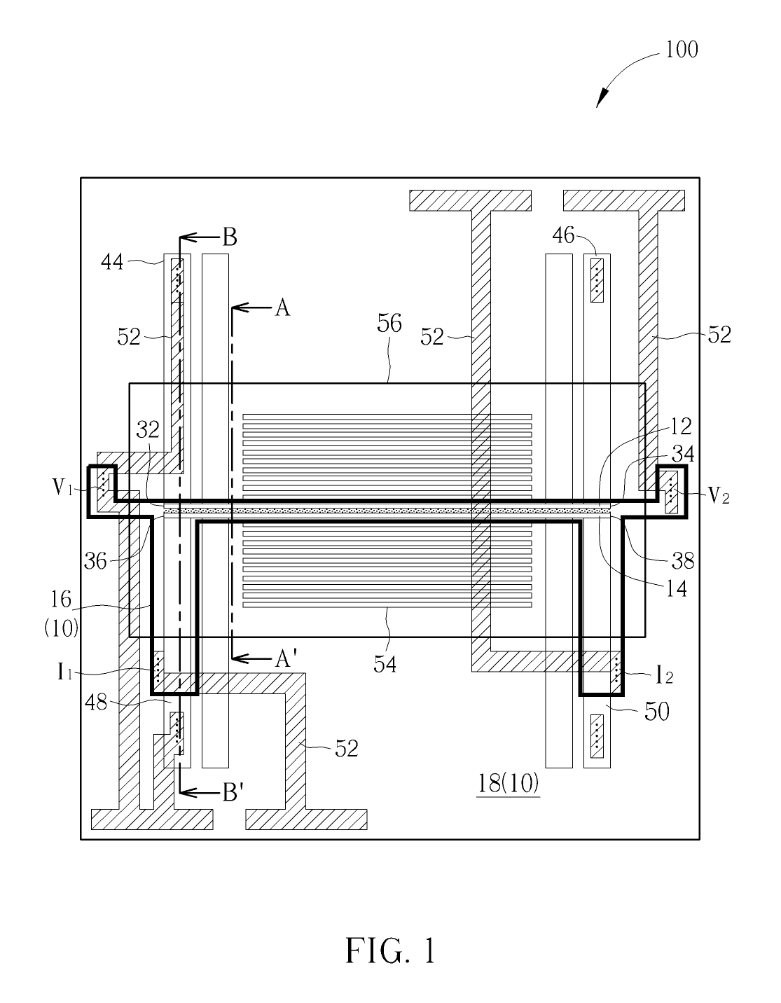

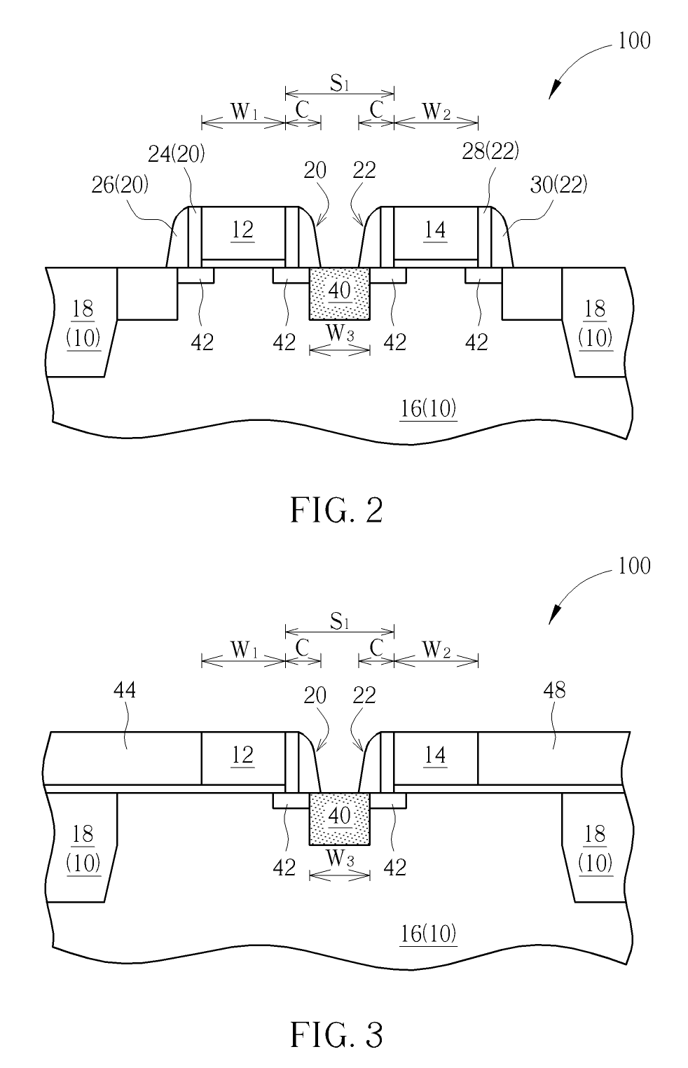

The present invention now will be described more fully hereinafter with reference to the accompanying drawings, wherein like numbers refer to like elements throughout. A test structure for measuring doping region resistance will be described with reference to the accompanying FIG. 1 to FIG. 3. FIG. 1 shows a top view of a test structure for measuring a doping region resistance schematically. FIG. 2 shows schematically a cross- sectional view of the test structure in FIG. 1 along line A-A′ . FIG. 3 shows schematically a cross-sectional view of the test structure in FIG. 1 along line B-B′ .

Please refer to FIG. 1 and FIG. 2. A test structure for measuring doping region resistance 100 includes a pair of gate lines such as a first gate line 12 and a second gate line 14 disposed on a substrate 10. The substrate 10 may be a wafer 10. The substrate 10 is divided into an active area 16 and an isolation area 18. The active area 16 is framed by thick line in the figures. The first gate line 12 and the second gate line 14 are disposed on the active area 16 of the substrate 10, parallel and adjacent to each other. A width W₁ of the first gate line 12 and a width W₂ of a second gate line 14 are preferably the same. A space S₁ is disposed between the first gate line 12 and the second gate line 14. Two first spacers 20 are disposed on two sidewalls of the first gate line 12 respectively. Two second spacers are disposed on two sidewalls of the second gate line 14 respectively. One of the first spacers 20 opposes to one of the second spacer 22. Each of the first spacer 20 includes an offset spacer 24 and a main spacer 26. Similarly, each of the second spacer 22 includes an offset spacer 28 and a main spacer 30. The first spacer 20 and the second spacer 22 have the same critical dimension C. The first gate line 12 has a front end 32 and a back end 34 which respectively refer to two end points of the first gate line 12. The second gate line 14 has a front end 36 and a back end 38 which respectively refer to two end points of the second gate line 14. A doping region 40 such as a source/drain doping region is disposed within the within the active area 16 of the substrate 10 and between the first spacer 20 and the second spacer 22 which facing each other. The doping region 40 may include p-type dopants or n-type dopants. Furthermore, the doping region 40 positioned along the first gate line 12 and extends continuously from the front end 32 to the back end 34. Moreover, the doping region 40 partly overlaps with one of the first spacers 20 and one of the second spacers 22. Specifically, the doping region 40 also extends continuously from one of the first spacers 20 to one of the second spacers 22. There are lightly doping regions 42 disposed under the first gate line 12 and the second gate line 14.

Please refer to FIG. 1 and FIG. 3. At least a first auxiliary gate line 44 is disposed perpendicular to the first gate line 12 and connecting to the front end 32 of the first gate line 12. At least a third auxiliary gate line 46 is disposed perpendicular to the first gate line 12 and connecting to the back end 34 of the first gate line 12. However, the number of the first auxiliary gate line 44 and the number of the third auxiliary gate line 46 are not limited. There can be more than one first auxiliary gate line 44 and more than one third auxiliary gate line 46 disposed near or at the ends of the first gate line 12. Similarly, at least a second auxiliary gate line 48 is disposed perpendicular to the second gate line 14 and connecting to the front end 36 of the second gate line 14. At least a fourth auxiliary gate line 50 is disposed perpendicular to the second gate line 14 and connecting to the back end 38 of the second gate line 14. However, the number of the second auxiliary gate line 48 and the number of the fourth auxiliary gate line 50 are not limited. There can be numerous second auxiliary gate lines 48 and numerous fourth auxiliary gate lines 50 disposed near or at the ends of the second gate line 14. The auxiliary gate lines 44/46/48/50 are used to keep currents only flow through the doping region 40 in the subsequent measurement technique.

As shown in FIG. 1, a voltage terminal V₁ couples to the doping region 40 disposed around the front end 32 of the first gate line 12. The voltage terminal V₁ also couples the first gate line 12, the second gate line 14, the first auxiliary gate line 44, the second auxiliary gate line 48, the third auxiliary gate line 46, and the fourth auxiliary gate line 50. Another voltage terminal V₂ couples only to the doping region 40 around the back end 34 of the first gate line 12. Moreover, a current detecting terminal I₁ couples to the doping region 40 around the front end 32 of the first gate line 12. Another current detecting terminal couples I₂ to the doping region 40 at the back end 34 of the first gate line 12.

The above-mentioned coupling may be achieved by utilizing metal wires 52 or diffusion areas. The diffusion area includes the active area 16, and the doping region 40 within the active area 16.

The voltage terminals V₁/V₂ and the current detecting terminals I₁/I₂ may electrically connect to redistribution lines.

Please refer to FIG. 1 again. A plurality of dummy gates 54 may be selectively formed parallel to the first gate line 12 and second gate line 14 for improving the exposure quality of the first gate line 12 and the second gate line 14 during the lithographic process. Moreover, a silicide alignment block 56 may be formed on the substrate 10.

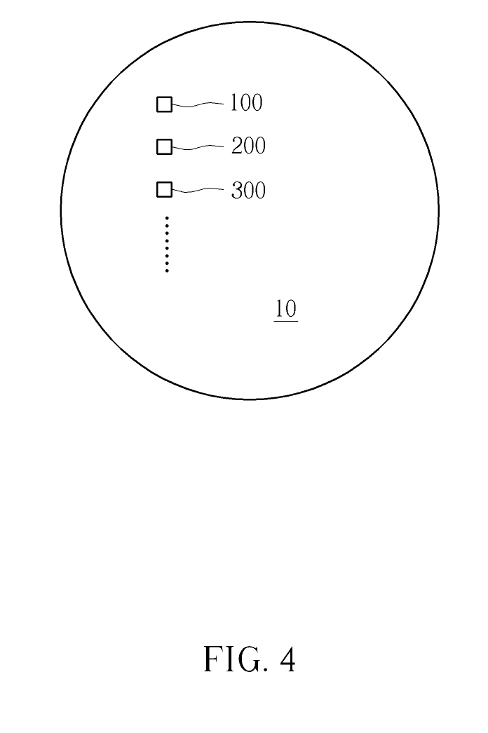

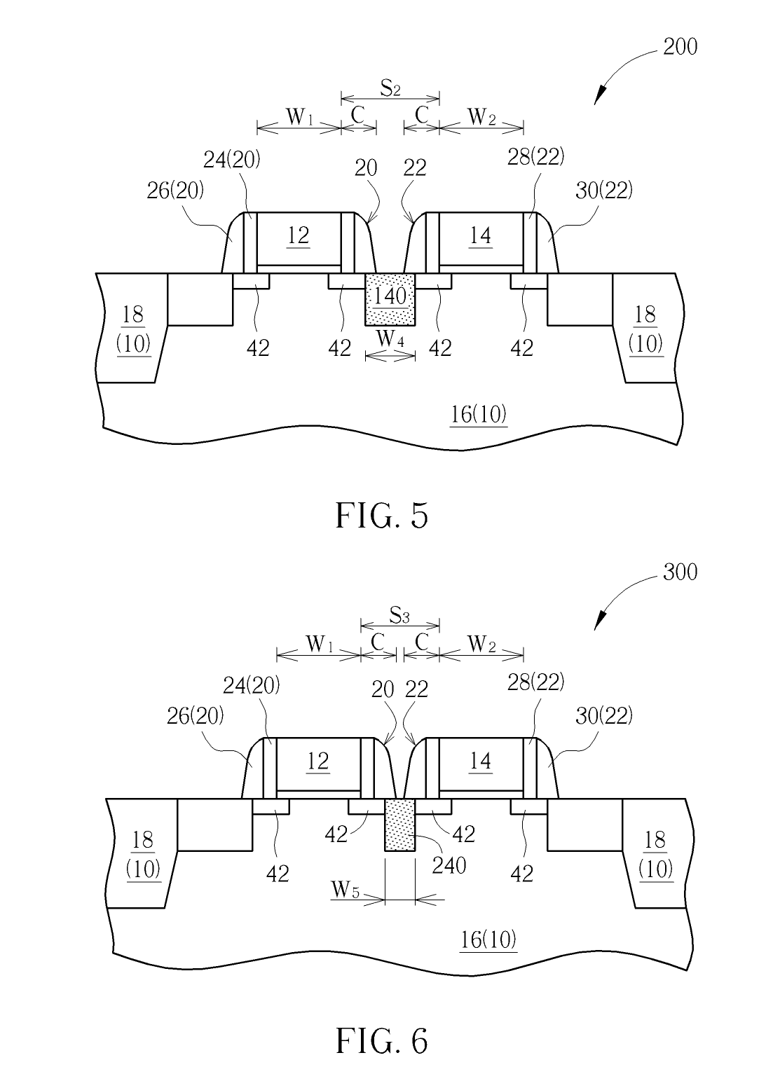

According to a preferred embodiment of the present invention, the test structure 100 is positioned on the scribe line, but not limited to such case. As shown in FIG. 4, the test structure 100 can be disposed on any region of the wafer 10 based on different requirements. Moreover, there can be other test structures provided on the wafer 10. For example, the test structures 200/300 can be disposed on the wafer 10 together with the test structure 100. Furthermore, the difference between the test structures 100/200/300 is that each test structure 100/200/300 has a different space S₁/S₂/S₃ between the first gate line 12 and the second gate line 14, respectively. FIG. 5 illustrates cross-sectional views of another test structure. FIG. 6 illustrates cross-sectional views of yet another test structure. As shown in FIG. 2, FIG. 5 and FIG. 6, the space S₁ of the test structure 100 is greater than the space S₂ of the test structure 200, and the space S₂ of the test structure 200 is greater than the space S₃ of the test structure 300. It is noteworthy that the first gate line 12 of each test structure 100/200/300 still have the same width W₁, and the second gate line 14 of each test structure 100/200/300 also have the same width W₂. The width W₁ is preferably equal to the width W₂. Furthermore, the first spacer 20 of each test structure 100/200/300 have the same critical dimension C, and the second spacer 22 of each test structure 100/200/300 also have the same critical dimension C. However, the size of the doping region 40/140/240 between the opposing first spacer 20 and the second spacer 22 of each test structure 100/200/300 is different. More specially speaking, a width W₃/W₄/W₅ of the doping region 40/140/240 of each test structure 100/200/300 is different, and the width W₃/W₄/W₅ of the doping region 40/140/240 of each test structure 100/200/300 is proportional to the space S₁/ S₂/ S₃ of each test structure 100/200/300. However, a length of the doping region 40/140/240 of each test structure 100/200/300 is substantially identical to each other, and a concentration of dopants in each doping region 40/140/240 is also substantially identical to each other. Other elements in the test structure 200/300 are disposed at the same position with the same size as the elements in the test structure 100. Please refer to FIG. 1 and FIG. 2 for reference, the accompanying description is therefore omitted here.

The following description will illustrate a measurement technique practiced by the test structure introduced above. FIGS. 1 to 8 respectively illustrate a method of measuring a critical dimension of a spacer according to a preferred embodiment of the present invention. As shown in FIG. 4, first, a plurality of test structures 100/200/300 are provided on the wafer 10. The detail structures of the test structures 100/200/300 are described in the above paragraphs and an accompanying explanation is therefore omitted. The number of the test structures can be adjusted depended on different requirements. Please refer to FIG. 1 to FIG. 6, latter, a voltage difference is applied to the voltage terminal V₁, and the voltage terminal V₂ of each test structure 100/200/300, so the doping region 40/140/240 of each test structure 100/200/300 undergoes the voltage difference V. Then, current flows through each doping region 40/140/240 of each test structure 100/200/300 is measured by detecting the current detecting terminal I₁ and the current detecting terminal I₂ of each test structure 100/200/300 to get several current values corresponding to each doping region 40/140/240. Because the sizes of the doping regions 40/140/240 are different, different doping regions 40/140/240 will have its specific current flows through it. After that, a reciprocal of resistance of each doping region can be calculated by the following formula:

1/resistance=current value/voltage difference

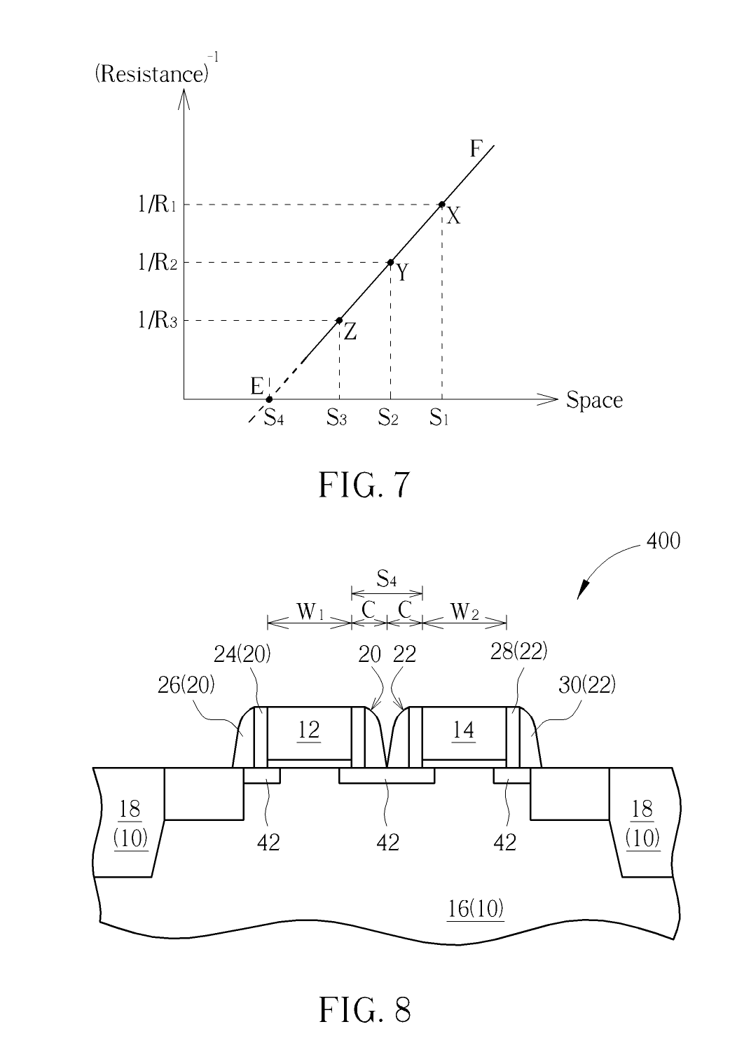

Then, as showing in FIG. 7, a plot of reciprocal of resistance versus space of test structure is provided based on the reciprocal of resistance of each doping region 40/140/240, and the space S₁/S₂/S₃ of each test structure 100/200/300. For example, as shown in FIG. 7, a dot X represents the reciprocal of resistance 1/R₁ of the doping region 40 and the corresponding space S₁ of the test structure 100. A dot Y represents the reciprocal of resistance 1/R₂ of the doping region 140 and the corresponding space S₂ of the test structure 200. A dot Z represents the reciprocal of resistance 1/R₃ of the doping region 240 and the corresponding space S₃ the test structure 300. There may be more dots if more test structures are tested.

After that, a correlation F can be formed by making regression based on the dots X/Y/ Z on the plot. Thereafter, extrapolating the correlation F back to 0 unit of reciprocal of resistance to get an intersection point with the axis of space of test structure. The intersection point E corresponds to the space S₄ on the axis of the space of test structure. The space S₄ equals to two times of the critical dimension C of the first spacer 20 shown in FIG. 2. Then, the critical dimension C of the first spacer 20 can be calculated by dividing the space S₄ by 2.

The following paragraphs explain reasons why the critical dimension C of the first spacer 20 can be calculated by dividing the space S₄ by 2. FIG. 8 illustrates a cross-sectional view of a test structure having smallest space. As shown in FIG. 8, when the first gate line 12 and the second gate line 14 has a space S₄, which is the smallest space, between them, it means that the first gate line 12 and the second gate line 14 can not be any closer to each other. At this point, the first spacer 20 and the second spacer 22 contact each other, and a width of a doping region (not shown) between the first gate line 12 and the second gate line 14 in FIG. 8 is substantially 0. In other words, there is no doping region between the first gate line 12 and the second gate line 14 in this situation. Because there is no doping region between first gate line 12 and the second gate line 14, the current value will be extremely small when applying the voltage difference to the voltage terminal V₁, and the voltage terminal V_{2.} Therefore, it can be calculated that the reciprocal of resistance of the doping region in FIG. 8 is approximate to 0 based on the above mentioned formula.

Now it can be concluded that when the reciprocal of resistance is 0, the first spacer 20 and the second spacer 22 contact each other, and the first gate line 12 and the second gate line 14 has a space S₄.

Please still refer to FIG. 8. The space S₄ is equal to the addition of the critical dimension C of the first spacer 20 and the critical dimension C of the second spacer 22. As the first spacer 20 and the second spacer 22 has the same critical dimension C, the space S₄ equals to two times of the critical dimension C of first spacers 20. Finally, the critical dimension C of the first spacer 20 can be calculated by dividing the space S₄ by 2.

According to the teaching of the present invention, by utilizing the test structures disclosed in the present invention, a critical dimension of a spacer can be calculated by measuring the current flowing through the doping region of each test structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A structure for measuring doping region resistance, comprising:
a substrate;
a first gate line disposed on the substrate;
a second gate line disposed parallel and adjacent to the first gate line;
a first spacer disposed one a sidewall of the first gate line;
a second spacer opposing to the first spacer disposed on a sidewall of the second gate line; and
a doping region disposed within the substrate between the first spacer and the second spacer, and the doping region extend continuously along the first gate line from a front end of the first gate line to a back end of the first gate line.

2. The structure for measuring doping region resistance of claim 1, wherein a width of the first gate line is substantially equal to a width of the second gate line.

3. The structure for measuring doping region resistance of claim 1, further comprising a first auxiliary gate disposed perpendicular to the first gate line and connecting to the front end of the first gate line.

4. The structure for measuring doping region resistance of claim 1, further comprising a second auxiliary gate disposed perpendicular to the second gate line and connecting to a front end of the second gate line.

5. The structure for measuring doping region resistance of claim 1, further comprising a third auxiliary gate disposed perpendicular to the first gate line and connecting to the back end of the first gate line.

6. The structure for measuring doping region resistance of claim 1, further comprising a fourth auxiliary gate disposed perpendicular to the second gate line and connecting to a back end of the second gate line.

7. The structure for measuring doping region resistance of claim 1, further comprising a first voltage terminal coupling to the doping region at the front end of the first gate line.

8. The structure for measuring doping region resistance of claim 1, further comprising a second voltage terminal coupling to the doping region at the back end of the first gate line.

9. The structure for measuring doping region resistance of claim 1, further comprising a plurality of dummy gates disposed parallel to the first gate line and second gate line.

10. The structure for measuring doping region resistance of claim 1, further comprising a first current detecting terminal coupling to the doping region at the front end of the first gate line.

11. The structure for measuring doping region resistance of claim 1, further comprising a second current detecting terminal coupling to the doping region at the back end of the first gate line.

12. A method of measuring a critical dimension of a spacer, comprising the steps of:
(a) providing numerous test structures, each of the test structures comprising:
a substrate;
a first gate line disposed on the substrate;
a second gate line disposed parallel and adjacent to the first gate line;
a first spacer disposed on one a sidewall of the first gate line;
a second spacer opposing to the first spacer disposed on a sidewall of the second gate line, wherein each of the test structures has a doping region different in size, the doping region is disposed in the substrate and between the first gate line and the second gate line, and each of the test structures has a space disposed between the first gate line and the second gate line, and the space of each of the test structures is different;
(b) applying a voltage difference to each of the doping regions, and measuring a current flowing through each of the doping region under the voltage difference to get several current values;
(c) calculating a reciprocal of resistance of each of the doping regions based on the current values and the voltage difference;
(d) drawing a plot of reciprocal of resistance versus space based on the reciprocal of resistance of each test structure and the space of each test structure;
(e) making regression of the plot to form a correlation; and
(f) extrapolating the correlation back to 0 unit of reciprocal of resistance to determining two times of a critical dimension of the first spacer.

13. The method of measuring a critical dimension of a spacer of claim 12, wherein the first spacer comprises an offset spacer and a main spacer.

14. The method of measuring a critical dimension of a spacer of claim 12, wherein the test structures are disposed on a scribe line of a wafer.
